(19) United States
(12) Patent Application Publication
(10) Pub. No.: US 2014/0261661 A1
(43) Pub. Date: Sep. 18, 2014

(54) FREE-STANDING METALLIC ARTICLE WITH OVERPLATING

(71) Applicant: GTAT CORPORATION, Nashua, NH (US)

(72) Inventors: Steve Babayan, Los Altos, CA (US); Robert Brainard, Sunnyvale, CA (US); Arvind Chari, Saratoga, CA (US); Alejandro de la Fuente Vornbrock, San Carlos, CA (US); Venkatesan Murali, San Jose, CA (US); Gopal Prabhu, San Jose, CA (US); Arthur Rudin, Morgan Hill, CA (US); Venkateswaran Subbaraman, San Jose, CA (US); David Tanner, San Jose, CA (US); Dong Xu, Fremont, CA (US)

(73) Assignee: GTAT CORPORATION, Nashua, NH (US)

(21) Appl. No.: 14/139,705

(22) Filed: Dec. 23, 2013

Related U.S. Application Data
(63) Continuation-in-part of application No. 13/798,123, filed on Mar. 13, 2013.

(51) Int. Cl. H01L 31/0224; H01L 31/18

(52) U.S. Cl. CPC H01L 31/022425; H01L 31/18
USPC 136/256; 205/67

(57) ABSTRACT

A free-standing metallic article, and method of making, is disclosed in which the metallic article is electroformed on an electrically conductive mandrel. The mandrel has an outer surface layer having a preformed pattern. The outer surface layer has a dielectric region and an exposed metal region. The metallic article has a plurality of electroformed elements that are formed on the exposed metal region of the outer surface layer of the electrically conductive mandrel. A first electroformed element has an overplated portion formed above the outer surface layer of the mandrel. The metallic article is configured to serve as an electrical conduit for a photovoltaic cell, and forms a unitary, free-standing piece when separated from the electrically conductive mandrel.

### RELATED APPLICATIONS

This application is a continuation-in-part of Babayan et al., U.S. patent application Ser. No. 13/798,123 entitled “Free-Standing Metallic Article for Semiconductors” and filed on Mar. 13, 2013, which is owned by the assignee of the present application and is hereby incorporated by reference.

### BACKGROUND OF THE INVENTION

A solar cell is a device that converts photons into electrical energy. The electrical energy produced by the cell is collected through electrical contacts coupled to the semiconductor material, and is routed through interconnections with other photovoltaic cells in a module. The “standard cell” model of a solar cell has a semiconductor material, used to absorb the incoming solar energy and convert it to electrical energy, placed below an anti-reflective coating (ARC) layer, and above a metal backsheet. Electrical contact is typically made to the semiconductor surface with fire-through paste, which is metal paste that is heated such that the paste diffuses through the ARC layer and contacts the surface of the cell. The paste is generally patterned into a set of fingers and bus bars which will then be soldered with ribbon to other cells to create a module. Another type of solar cell has a semiconductor material sandwiched between transparent conductive oxide layers (TCO's), which are then coated with a final layer of conductive paste that is also configured in a finger/bus bar pattern.

In both these types of cells, the metal paste, which is typically silver, works to enable current flow in the horizontal direction (parallel to the cell surface), allowing connections between the solar cells to be made towards the creation of a module. Solar cell metallization is most commonly done by screen printing a silver paste onto the cell, curing the paste, and then soldering ribbon across the screen printed bus bars. However, silver is expensive relative to other components of a solar cell, and can contribute a high percentage of the overall cost.

To reduce silver cost, alternate methods for metallizing solar cells are known in the art. For example, attempts have been made to replace silver with copper, by plating copper directly onto the solar cell. However, a drawback of copper plating is contamination of the cell with copper, which impacts reliability. Plating throughput and yield can also be issues when directly plating onto the cell due to the many steps required for plating, such as depositing seed layers, applying masks, and etching or laser scribing away plated areas to form the desired patterns. Other methods for forming electrical conduits on solar cells include utilizing arrangements of parallel wires or polymeric sheets encasing electrically conductive wires, and laying them onto a cell.

### SUMMARY OF THE INVENTION

A free-standing metallic article, and method of making, is disclosed in which the metallic article is electroformed on an electrically conductive mandrel. The mandrel has an outer surface layer having a preformed pattern. The outer surface layer has a dielectric region and an exposed metal region. The metallic article has a plurality of electroformed elements that are formed on the exposed metal region of the outer surface layer of the electrically conductive mandrel. A first electroformed element has an overplated portion formed above the outer surface layer of the mandrel. The metallic article is configured to serve as an electrical conduit for a photovoltaic cell, and forms a unitary, free-standing piece when separated from the electrically conductive mandrel.

### BRIEF DESCRIPTION OF THE DRAWINGS

Each of the aspects and embodiments of the invention described herein can be used alone or in combination with one another. The aspects and embodiments will now be described with reference to the attached drawings.

FIG. 1 shows a perspective view of an exemplary electroforming mandrel in one embodiment.

FIGS. 2A-2C depict cross-sectional views of exemplary stages in producing a free-standing electroformed metallic article.

FIG. 3 provides a cross-sectional view of one embodiment of an electrically conductive mandrel.

FIG. 4 provides a cross-sectional view of another embodiment of an electrically conductive mandrel.

FIGS. 5A-5B are top views of two embodiments of metallic articles.

FIG. 5C is a cross-sectional view of section A-A of FIG. 5B.

FIGS. 5D-5E are partial cross-sectional views of yet further embodiments of the cross-section of FIG. 5B.

FIGS. 5F-5G are top views of embodiments of metallic articles with interconnection elements.

FIGS. 6A-6B are vertical cross-sections of electroformed elements with top surfaces having customized features, in certain embodiments.

FIGS. 7A-7B show cross-sectional views of an exemplary mandrel and corresponding electroformed element having an overplated portion.

FIG. 8 shows other embodiments of overplated shapes

FIG. 9 provides a cross-sectional view of embodiments of template metals that may be plated onto an electroforming mandrel, and embodiments of electroformed pieces that may be produced.

FIGS. 10A-10B are cross-sectional views of exemplary layers that may be plated on electroformed elements.

FIGS. 11A-11C are cross-sectional views of an electroformed element in which edge portions are etched prior to removing the element from the mandrel.

FIG. 12 is a flowchart of an exemplary method for forming metallic articles with overplated portions.

### DETAILED DESCRIPTION OF THE EMBODIMENTS

Metallization of solar cells is conventionally achieved with screen printed silver pastes on the surface of the cell, and cell-to-cell interconnections that utilize solder-coated ribbons. For a given aspect ratio of a metal conduit, the electrical resistance is inversely proportional to its footprint. Therefore, the cell metallization or cell-to-cell interconnection design usually trades off between shading and resistance for the most optimized solar cell module power output. The metallic articles of the present disclosure can be used to replace conventional silver paste and solder coated ribbons and have adaptable features that allow for decoupling of factors that conventionally require trade-offs between functional requirements. The metallic articles include overplated portions, which may include various features and layers to enhance its performance as an electrical conduit for a photovoltaic cell.

In Babayan et al., U.S. patent application Ser. No. 13/798,123, electrical conduits for semiconductors such as photovoltaic cells are fabricated as an electroformed free-standing metallic article. Additional electrical conduits are also disclosed in Babayan et al., U.S. patent application Ser. No. 14/079,540, entitled “Adaptable Free-Standing Metallic Article for Semiconductors” filed on Nov. 13, 2013; and in Brainard et al., U.S. patent application Ser. No. 14/079,544, entitled “Free-Standing Metallic Article With Expansion Segment” filed on Nov. 13, 2013, both of which are owned by the assignee of the present application and are hereby incorporated by reference. The metallic articles are produced separately from a solar cell and can include multiple elements such as fingers and bus bars that can be transferred stably as a unitary piece and easily aligned to a semiconductor device. The elements of the metallic article are formed integrally with each other in the electroforming process. The metallic article is manufactured in an electroforming mandrel, which generates a patterned metal layer that is tailored for a solar cell or other semiconductor device. For example, the metallic article may have grid lines with height-to-width aspect ratios that minimize shading for a solar cell. The metallic article can replace conventional bus bar metallization and ribbon stringing for cell metallization, cell-to-cell interconnection and module making. The ability to produce the metallization layer for a photovoltaic cell as an independent component that can be stably transferred between processing steps provides various advantages in material costs and manufacturing.

FIG. 1 depicts a perspective view of a portion of an exemplary electroforming mandrel 100 in one embodiment of U.S. patent application Ser. No. 13/798,123. The mandrel 100 may be made of electrically conductive material such stainless steel, copper, anodized aluminum, titanium, or molybdenum, nickel, nickel-iron alloy (e.g., Invar), copper, or any combinations of these metals, and may be designed with sufficient area to allow for high plating currents and enable high throughput. The mandrel 100 has an outer surface 105 with a preformed pattern that comprises pattern elements 110 and 112 and can be customized for a desired shape of the electrical conduit element to be produced. In this embodiment, the pattern elements 110 and 112 are grooves or trenches with a rectangular cross-section, although in other embodiments, the pattern elements 110 and 112 may have other cross-sectional shapes. The pattern elements 110 and 112 are depicted as intersecting segments to form a grid-type pattern, in which sets of parallel lines intersect perpendicularly to each other in this embodiment.

The pattern elements 110 have a height ‘H’ and width ‘W’, where the height-to-width ratio defines an aspect ratio. By using the pattern elements 110 and 112 in the mandrel 100 to form a metallic article, the electroformed metallic parts can be tailored for photovoltaic applications. For example, the aspect ratio may be between about 0.01 and about 10 as desired, to meet shading constraints of a solar cell.

The aspect ratio, as well as the cross-sectional shape and longitudinal layout of the pattern elements, may be designed to meet desired specifications such as electrical current capacity, series resistance, shading losses, and cell layout. Any electroforming process can be used. For example, the metallic article may be formed by an electroplating process. In particular, because electroplating is generally an isotropic process, confining the electroplating with a pattern mandrel to customize the shape of the parts is a significant improvement for maximizing efficiency. Furthermore, although certain cross-sectional shapes may be unstable when placing them on a semiconductor surface, the customized patterns that may be produced through the use of a mandrel allows for features such as interconnecting lines to provide stability for these conduits. In some embodiments, for example, the preformed patterns may be configured as a continuous grid with intersecting lines. This configuration not only provides mechanical stability to the plurality of electroformed elements that form the grid, but also enables a low series resistance since the current is spread over more conduits. A grid-type structure can also increase the robustness of a cell. For example, if some portion of the grid becomes broken or non-functional, the electrical current can flow around the broken area due to the presence of the grid pattern.

FIGS. 2A-2C are simplified cross-sectional views of exemplary stages in producing a metal layer piece using a mandrel, as disclosed in U.S. patent application Ser. No. 13/798,123. In FIG. 2A, a mandrel 102 with pattern elements 110 and 115 is provided. Pattern element 115 has a vertical cross-section that is tapered, being wider toward the outer surface 105 of the mandrel 102. The tapered vertical cross-section may provide certain functional benefits, such as increasing the amount of metal to improve electrical conductivity, or aiding in removal of the electroformed piece from the mandrel 102. The mandrel 102 is subjected to an electroforming process, in which exemplary electroformed elements 150, 152 and 154 are formed within the pattern elements 110 and 115 as shown in FIG. 2B. The electroformed elements 150, 152 and 154 may be, for example, copper only, or alloys of copper. In other embodiments, a layer of nickel may be plated onto the mandrel 102 first, followed by copper so that the nickel provides a barrier against copper contamination of a finished semiconductor device. An additional nickel layer may optionally be plated over the top of the electroformed elements to encapsulate the copper, as depicted by nickel layer 160 on electroformed element 150 in FIG. 2B. In other embodiments, multiple layers may be plated within the pattern elements 110 and 115, using various metals as desired to achieve the necessary properties of the metallic article to be produced.

In FIG. 2B the electroformed elements 150 and 154 are shown as being formed flush with the outer surface 105 of mandrel 102. Electroformed element 152 illustrates another embodiment in which the elements may be overplated. For electroformed element 152, electroplating continues until the metal extends above the surface 105 of mandrel 102. The overplated portion, which typically will form as a rounded top due to the isotropic nature of electroforming, may serve as a handle to facilitate the extraction of the electroformed element 152 from mandrel 102. The rounded top of electroformed element 152 may also provide optical advantages in a photovoltaic cell by, for example, being a reflective surface to aid in light collection. In yet other embodiments not shown, a metallic article may have portions that are formed on top of the mandrel surface 105, such as a bus bar, in addition to those that are formed within the preformed patterns 110 and 115.

In FIG. 2C the electroformed elements 150, 152 and 154 are removed from the mandrel 102 as a free-standing metallic article 180. Note that FIGS. 2A-2C demonstrate three different types of electroformed elements 150, 152 and 154. In various embodiments, the electroformed elements within the mandrel 102 may be all of the same type, or may have different combinations of electroformed patterns. The metallic article 180 may include intersecting elements 190, such as would be formed by the cross-member patterns 112 of FIG. 1. The intersecting elements 190 may assist in making the metallic article 180 a unitary, free-standing piece such that it may be easily transferred to other processing steps while keeping the individual elements 150, 152 and 154 aligned with each other. The additional processing steps may include coating steps for the free-standing metallic article 180 and assembly steps to incorporate it into a semiconductor device. By producing the metal layer of a semiconductor as a free-standing piece, the manufacturing yields of the overall semiconductor assembly will not be affected by the yields of the metal layer. In addition, the metal layer can be subjected to temperatures and processes separate from the other semiconductor layers. For example, the metal layer may be undergo high temperature processes or chemical baths that will not affect the rest of the semiconductor assembly.

After the metallic article 180 is removed from mandrel 102 in FIG. 2C, the mandrel 102 may be reused to produce additional parts. Being able to reuse the mandrel 102 provides a significant cost reduction compared to current techniques where electroplating is performed directly on a solar cell. In direct electroplating methods, masks or mandrels are formed on the cell itself, and thus must be built and often destroyed on every cell. Having a reusable mandrel reduces processing steps and saves cost compared to techniques that require patterning and then plating a semiconductor device. In other conventional methods, a thin printed seed layer is applied to a semiconductor surface to begin the plating process. However, seed layer methods result in low throughputs. In contrast, reusable mandrel methods as described herein can utilize mandrels of thick metal which allow for high current capability, resulting in high plating currents and thus high throughputs. Metal mandrel thicknesses may be, for example, between 0.2 to 5 mm.

FIGS. 3-4 are cross-sectional views of exemplary mandrels, demonstrating embodiments of various mandrel and pattern designs. In FIG. 3, a planar metal mandrel base 320 has a dielectric layer 330 laid over it. The pattern including pattern elements 310 for forming a metallic article are created in dielectric layer 330. The dielectric layer 330 may be, for example, a fluoropolymer (e.g., Teflon®), a patterned photoresist (e.g., Dupont Riston® thick film resist), or a thick layer of epoxy-based photoresist (e.g., SU-8). The photoresist is selectively exposed and removed to reveal the desired pattern. In other embodiments, the dielectric layer 330 may be patterned by, for example, machining or precision laser cutting. In this type of mandrel 300 with dielectric-surrounded pattern elements, electroplating will fill the trenches of pattern elements 310 from the bottom up, starting at the metal mandrel base 320. The use of dielectrics or permanent resists allows for reuse of the mandrel 300, which reduces the number of process steps, consumable costs, and increases throughput of the overall manufacturing process compared to consumable mandrels.

FIG. 4 shows another mandrel 400 made primarily of metal, including the cavities for forming a metallic article. When electroforming with metal mandrel 400, the metal surfaces of a pattern element 410 allow for rapid plating from all three sides of the trench pattern. In some embodiments of mandrel 400, a release layer 420 such as a dielectric or low-adhesion material (e.g., a fluoropolymer) may optionally be coated onto the mandrel 400, in various areas as desired. The release layer 420 may reduce adhesion of the electroformed part to the mandrel 400, or may minimize adhesion of a substrate, such as an adhesive film, that may used to peel the electroformed article from the mandrel. The release layer 420 may be patterned simultaneously with the metal mandrel, or may be patterned in a separate step, such as through photoresist with wet or dry etching. The pattern elements 410, 430 and 440 in the metal mandrel, may be, for example, grooves and intersecting trenches, and may be formed by, for instance, machining, laser cutting, lithography, or electroforming. In other embodiments, the mandrel 400 may not require a release layer 420 if the surface of the mandrel that is exposed to the plating solution is selected to have poor adhesion to the metallic article. For instance, for electroformed parts that will have a first layer (that is, an outer layer) of nickel plating, the mandrel 400 may be made of copper. Copper has low adhesion to nickel and thereby allows the formed, nickel-coated piece to be easily removed from the copper mandrel. When applying a release layer 420 to mandrel 400, the relative depth of the trench pattern element 410 in the metal and the thickness of the dielectric coating can be selected to minimize void formation of the metal piece formed within pattern element 410, while still enabling a high plating rate.

FIG. 4 shows a further embodiment in which the release layer 420 has been extended partially into the depth of pattern element 430. This extension of the coating into pattern element 430 may enable electroforming rates between that of dielectrically-surrounded pattern element 310 of FIG. 3 and metal-surrounded pattern element 410 of FIG. 4. The amount that release layer 420 extends into the pattern element 430 may be chosen to achieve a desired electroforming rate. In some embodiments, release layer 420 may extend into pattern element 430 by, for example, approximately half the amount of the pattern width. A pattern element 430 with release layer 420 extending into the trench can allow a more uniform electroplating rate within the trench, and hence, a more uniform grid can be produced. The amount that the dielectric or release layer 420 extends into the trench can be modified to optimize overall plating rate and plating uniformity.

FIG. 4 shows yet another embodiment of mandrel 400 in which the pattern element 440 has tapered walls. The tapered walls are wider at the outer surface 405 of mandrel 400, to facilitate removal of a formed metallic element from the patterned mandrel. In other embodiments not shown, the cross-sectional shape of the preformed patterns for any of the mandrels described herein may include shapes such as, but not limited to, curved cross-sections, beveled edges at the corners of a pattern's cross-section, curved paths along the length of a pattern, and segments intersecting each other at various angles to each other.

FIGS. 5A and 5B illustrate top views of exemplary metal layers 500a and 500b that may be produced by the electroforming mandrels described herein. Metal layers 500a and 500b include electroformed elements embodied here as substantially parallel fingers 510, which have been formed by substantially parallel grooves in an electrically conductive mandrel. Metal layer 500b also includes electroformed elements embodied here as horizontal fingers 520 that intersect vertical fingers 510, where the fingers 510 and 520 intersect at approximately a perpendicular angle. In other embodiments, fingers 510 and 520 may intersect at other angles, while still forming a continuous grid or mesh pattern. Metal layers 500a and 500b also include a frame element 530 which may serve as a bus bar to collect current from the fingers 510 and 520. Having a bus bar integrally formed as part of the metallic article can provide manufacturing improvements. In present high-volume methods of solar module production, cell connections are often achieved by manually soldering metal ribbons to the cells. This commonly results in broken or damaged cells due to manual handling and stress imparted on the cells by the solder ribbons. In addition, the manual soldering process results in high labor-related production costs. Thus, having a bus bar or ribbon already formed and connected to the metallization layer, as is possible with the electroformed metallic articles described herein, enables low-cost, automated manufacturing methods.

Frame element 530 may also provide mechanical stability such that metal layers 500a and 500b are unitary, free-standing pieces when removed from a mandrel. That is, the metal layers 500a and 500b are unitary in that they are a single component, with the fingers 510 and 520 remaining connected, when apart from a photovoltaic cell or other semiconductor assembly. Frame element 530 may furthermore assist in maintaining spacing and alignment between finger elements 510 and 520 for when they are to be attached to a photovoltaic cell. Frame element 530 is shown in FIGS. 5A-5B as extending across one edge of metal layers 500a and 500b. However, in other embodiments, a frame element may extend only partially across one edge, or may border more than one edge, or may be configured as one or more tabs on an edge, or may reside within the grid itself. Furthermore, frame element 530 may be electroformed at the same time as the fingers 510 and 520, or in other embodiments may be electroformed in a separate step, after fingers 510 and 520 have been formed.

FIG. 5C shows a cross-section of metal layer 500b taken at section A-A of FIG. 5B. Fingers 510 in this embodiment are shown in as having aspect ratios greater than 1, such as about 1 to about 5, and such as approximately 2 in this figure. Having a cross-sectional height greater than the width reduces the shading impact of metal layer 500b on a photovoltaic cell. In various embodiments, only a portion of the fingers 510 and 520 may have an aspect ratio greater than 1, or a majority of the fingers 510 and 520 may have an aspect ratio greater than 1. In other embodiment, some or all of the fingers 510 and 520 may have an aspect ratio less than 1. Height ‘H’ of fingers 510 may range from, for example, about 5 microns to about 200 microns, or about 10 microns to about 300 microns. Width ‘W’ of fingers 510 may range from, for example, about 10 microns to about 5 mm, such as about 10 microns to about 150 microns. The distance between parallel fingers 510 has a pitch ‘P’, measured between the centerline of each finger. In some embodiments the pitch may range, for example, between about 1 mm and about 25 mm. In FIGS. 5B and 5C, the fingers 510 and 520 have different widths and pitches, but are approximately equivalent in height. In other embodiments, the fingers 510 and 520 may have different widths, heights and pitches as each other, or may have some characteristics that are the same, or may have all the characteristics the same. The values may be chosen according to factors such as the size of the photovoltaic cell, the shading amount for a desired efficiency, or whether the metallic article is to be coupled to the front or rear of the cell. In some embodiments, fingers 510 may have a pitch between about 1.5 mm and about 6 mm and fingers 520 may have a pitch between about 1.5 mm and about 25 mm. Fingers 510 and 520 are formed in mandrels having grooves that are substantially the same shape and spacing as fingers 510 and 520. Frame element 530 may have the same height as the fingers 510 and 520, or may be a thinner piece as indicated by the dashed line in FIG. 5C. In other embodiments, frame element 530 may be formed on above finger elements 510 and 520.

FIG. 5C also shows that fingers 510 and 520 may be substantially coplanar with each other, in that the fingers 510 and fingers 520 have a majority of their cross-sectional areas that overlap each other. Compared to conventional meshes that are woven over and under each other, a coplanar grid as depicted in FIG. 5C can provide a lower profile than overlapping circular wires of the same cross-sectional area. The intersecting, coplanar lines of metal layer 500b are also formed integrally with each other during the electroforming process, which provides further robustness to the free-standing article of metal layer 500b. That is, the integral elements are formed as one piece and not joined together from separate components. FIGS. 5D and 5E show other embodiments of coplanar, intersecting elements. In FIG. 5D, finger 510 is shorter in height than finger 520 but is positioned within the cross-sectional height of finger 520. Fingers 510 and 520 have bottom surfaces 512 and 522, respectively, that are aligned in this embodiment, such as to provide an even surface for mounting to a semiconductor surface. In the embodiment of FIG. 5E, finger 510 has a larger height than finger 520 and extends beyond the top surface of finger 520. A majority of the cross-sectional area of finger 510 overlaps the entire cross-section of finger 520, and therefore fingers 510 and 520 are coplanar as defined in this disclosure.

FIGS. 5F and 5G show yet other embodiments, in which electroformed metallic articles enable interconnections between photovoltaic cells in a module. A typical module has many cells, such as between 36-60, connected in series. The connections are made by attaching the front of one cell to the back of the next cell using solder-coated copper ribbon. Attaching the ribbon in this way requires a ribbon that is thin, so that the ribbon can bend around the cells without breaking the cell edges. Because a ribbon is already narrow, using a thin ribbon increases the resistance even further. The interconnections also typically require three separate ribbons, each soldered separately. In the embodiment of FIG. 5F, a metallic article 550 has interconnection elements 560 that have been integrally electroformed with a first grid region 570. Interconnection elements 560 have a first end coupled to grid 570, and are configured to extend beyond the surface of a photovoltaic cell to allow connection to a neighboring cell. The interconnection elements 560 replace the need for a separate ribbon to be soldered between cells, thus reducing manufacturing costs and enabling possible automation. In the embodiment shown, interconnection elements 560 are linear segments, although other configurations are possible. Also, the number of interconnection elements 560 can vary as desired, such as providing multiple elements 560 to reduce resistance. Interconnection elements 560 may be bent or angled after electroforming, such as to enable a front-to-back connection between cells, or may be fabricated in the mandrel to be angled relative to the grid 570.

The opposite end of interconnection elements 560 may be coupled to a second region 580, where the second region 580 may also be electroformed in an electrically conductive mandrel as part of the metallic article 550. In FIG. 5F, the second region 580 is configured as a tab—e.g., a bus bar—that may then be electrically connected to an electrical conduit 590 of a neighboring cell. The conduit 590 is configured here as an array of elements, but other configurations are possible. Grid 570 may, for example, serve as an electrical conduit on a front surface of a first cell, while grid 590 may be an electrical conduit on a rear surface of a second cell. In the embodiment of FIG. 5G, a metallic article 555 has a mesh instead of a bus bar type of connection. Metallic article 555 includes first region 570, interconnection elements 560 and second region 590 that have all been electroformed as a single component, such that the inter-cell connections are already provided by metallic article 555. Thus the metallic articles 550 and 555 provide electrical conduits not only on a surface of one photovoltaic cell, but also the interconnections between cells.

FIGS. 6A-6B show vertical cross-sections of exemplary electroformed elements 610 and 620, as disclosed in U.S. patent application Ser. No. 14/079,540. The cross-sections 610 and 620 are similar to electroformed elements 150 and 152 of FIG. 2B, and are presented in FIGS. 6A-6B to demonstrate further customized features that may be incorporated into the top surfaces of metallic articles in the present disclosure. In FIG. 6A, element 610 has a rectangular cross-section with a top surface 615, where “top” refers to the light-incident surface when mounted on a photovoltaic cell. Top surface 615 may be configured to contribute to optical properties of the grid lines, such as to promote light reflection and thus enhance cell efficiency. In some embodiments, the texturing may be an intentional roughness to increase the surface area for capturing light. The roughness may be imparted, for example, by having a textured pattern incorporated into the electroforming mandrel. That is, the preformed pattern 110 of FIG. 1 may have a texture pattern formed into the mandrel 100, where the top surface 615 would be the surface produced by the bottom of preformed pattern 110. In another embodiment, the texturing may be produced by the electroforming process itself. In one exemplary process, a high electroplating current may be used for a fast electroforming rate, such as on the order of 1 to 3 μm/minute. This fast rate can result in the exposed surface—at the outer surface 105 of electroforming mandrel 100—being rough.

In yet other embodiments, a custom-configured top surface may be a particular surface finish that is created after formation of the electroformed part. For example, FIG. 6B shows an overplated element 620 having a coating layer 622 on its top surface 625. Coating 622 may include one or more layers of metals including, but not limited to, nickel, silver, tin, lead-tin or a solder. The coating 622 may, for example, produce a smooth surface to improve reflectivity of the rounded top surface 625. Applying solder as a coating on top surface 625, or 615, can also assist in enabling solder reflow for bonding, in addition to providing optical benefits.

Although element 610 is shown with a rectangular cross-section and element 620 is shown with a rectangular base and rounded top, other cross-sectional shapes are possible such as a hemisphere or elongated rectangle with rounded chamfers. These cross-sectional shapes may be the same throughout a metallic article or vary between different zones of the metallic article. Any curved or rounded edges of the top surface may be utilized to deflect incident light to the cell or reflect light to enable total internal reflection if inside a standard solar cell module. The surfaces may be coated with a highly reflective metal such as silver or tin to enhance both deflection and reflection, thus reducing the effective mesh shading area to less than its footprint.

Although the mandrels disclosed herein are shown for forming single metallic articles or electroformed elements, the mandrels may also be configured to form multiple articles. For example, a mandrel may include patterns to form more than one metallic article 500a or 500b, such as to create a desired number of electrical conduit grids for a complete solar array.

FIG. 7A shows an exemplary mandrel 700 having an outer surface layer 710, with exposed metal regions 712 and dielectric regions 714 covering portions of the metal substrate 720. The mandrel 700 can be created by applying a dielectric coating to the base metal 720, followed by patterning to selectively expose the base metal. Patterning of the dielectric can be performed by, for example, photolithography, laser ablation, screen printing, or stencil printing. For example, a photoresist can be applied to the surface of the dielectric 714, exposed with a photomask, and then developed to create the patterned mandrel. The exposed metal regions 712 have a preformed pattern for determining the shape of the metallic article which will be formed. In this embodiment, the metal regions 712 are a surface of the electrically conductive mandrel and are configured as a groove, such as a rectangular groove. The dielectric material of dielectric regions 714 may be organic—such as epoxy, acrylic, urethane, vinyl, silicone, or nitrile compounds and polymers, fluorinated or non-fluorinated—or inorganic, such as silicon dioxide, silicon nitride, aluminum oxide or various other glasses and ceramics. The thickness of the dielectric coating may be on the order of nanometers to hundreds of microns, such as 50 nm to 300 microns. In some embodiments, the dielectric material may include more than one layer. In other embodiments, both the metal and dielectric can be constructed from multiple layers. For example, metal substrate 720 may include copper and titanium, or copper and nickel, coated with dielectric layers of silicon nitride and silicone polymers, or epoxy polymers and acrylate based polymers. The materials for metal substrate 720 and dielectric regions 714 may be chosen to enhance the reusability of the mandrel 700. For example, mandrel 700 may be treated with dichromate or may include low adhesion layers such as fluorinated small molecules and polymers, stainless steel, and titanium to facilitate cleaning of the mandrel. In other embodiments, the dielectric material of dielectric regions 714 may be stripped off of substrate 720 and new dielectric layers reapplied, such that the lifetime of substrate 720 is lengthened even further.

Also shown in FIG. 7A is an electroformed element 750. Electroformed element 750 is formed on exposed metal region 712, and is overplated onto outer surface layer 710 of mandrel 700. The overplating is the portion of the electroformed element that extends beyond the surface of the patterned dielectric layer. FIG. 7B shows electroformed element 750 when separated from the mandrel 700, where overplated portion 752 has a height 760 that spans a percentage of the overall height 765 of electroformed element 750. The overall height 765 includes the height 760 of overplated portion 752, as well as the height of stem portion 754 (as delineated by a dashed line). The height 760 of the overplated portion 752 may be a percentage of the overall height 765 of the electroformed element 750, where the percentage may vary in different embodiments. In some embodiments, the height 760 may span a majority, such as greater than 50%, of the overall height 765. In further embodiments, the height 760 may encompass the entire height 765 such that no stem region is present. As described previously in relation to FIGS. 6A and 6B, the overplated configuration may provide optical advantages due to the rounded top surface 754 of overplated portion 752. Furthermore, top surface 754 may be designed to assist in reflection of light to enhance the efficiency of a solar cell. For instance, the top surface 754 may be textured to create a Lambertian surface, or in other embodiments the top surface 754 may be coated, such as with silver, to enhance specular reflection.

The amount of electroforming and the dimensions of the exposed metal regions on the mandrel determine the extent of the electroformed shape that is formed. The deposition of metal is unconstrained by the mandrel, allowing overplating above the dielectric region of the outer surface layer. In the embodiments of FIGS. 6B, 7A and 7B, the overplated portions are approximately hemispherical. FIG. 8 provides cross-sections of other exemplary embodiments of overplated shapes that may be formed. In one embodiment, electroformed element 800 is a truncated circular cross-sectional shape, having more area than a hemisphere. This type of element 800 may be produced by, for example, increasing the electroforming time or current significantly compared to that for forming hemispherical overplated portion 752 of FIG. 7B. In another example, electroformed element 850 has a rectangular cross-section with rounded corners. This shape may be produced using, for example, a wider metal mandrel region compared to element 800. Bottom corners 855 may also be slightly rounded due to the nature of the electroplating process.

The shape of the overplated portions in the present disclosure can be further modified by the use of pulsed plating techniques, shielding of portions of the anode or cathode, modifications to the shape and placement of the anode, adjustments to the anode/cathode distance, and modifications to the fluid flow impinging on the electroformed part such that the shape can be made narrower and taller allowing for a hyperbolic or elliptical shape and even permitting a narrowing of the protruding electroform such that a conical shape is approximated. In further embodiments, the overplated region can also be adjusted in shape through the use of resists of multiple heights. For example, a resist of greater height may be placed on one side of the open trench, in opposition to a resist of lower height—e.g., making resist 714 in FIG. 7A thicker on the left side of exposed portion 712 than the resist 714 on the right side of exposed portion 712. In such an example, the overplated section will show a hemispherical surface on one side of the plated area (i.e. the lower side), but will have a flat alternate side opposing the thicker resist. This double resist method can also be used to create other effects, for example, clean hole formation, or dimpling, in the produced part.

FIG. 9 illustrates other electroforming embodiments in which a template metal may be plated onto the mandrel 900, to at least partially fill grooves formed by the exposed metal regions and dielectric regions in the outer surface layer of the mandrel. In one embodiment, template metal 920 is plated to fill the groove defined by exposed metal region 912a and surrounding dielectric regions 914, so that template metal 920 is approximately flush with the top of outer surface layer 910 of mandrel 900. Electroformed element 925 illustrates an exemplary piece that will be produced by overplating on the template metal 920, in which a flat bottom surface 927 is created. That is, electroformed element 925 is absent of a stem portion (e.g., stem portion 754 of FIG. 7B) due to template metal 920 being flush with outer surface layer 910. Thus, the overplated portion comprises the entire height of the electroformed element 925. In another embodiment, template metal 930 partially fills the groove over exposed metal region 912b to produce an electroformed element 935 having a shorter stem portion 937 compared to stem portion 754 of FIG. 7B where no template metal is in the mandrel groove. In a yet further embodiment, a template metal 940 is slightly overfilled in the groove of exposed metal region 912c, so that template metal 940 forms an upper surface 942 having a convex contour. As a result, electroformed element 945 that is formed on template metal 940 has a concave bottom surface 947. The non-planar bottom surface 947 may provide benefits such as allowing solder to wick underneath electroformed element 945 when being joined to a solar cell, thus increasing the joint strength due to the increased amount of solder or other adhering material.

Thus, FIG. 9 demonstrates that employing a template metal such as 920, 930 or 940 at the electroforming regions of the electroforming mandrel can impart specific shapes to the electroformed elements. The template metal is electrically conductive, allowing metal elements to be electroformed thereon, but also may have poor adhesion with the electroformed element, which permits removal of the electroformed articles while the template metal remains on the mandrel. Thus, the template metal can remain in the mandrel and be reused after a metallic article has been produced and removed from the mandrel. Template metal may be, for example, nickel, copper, tin, lead, tin/lead, silver, or gold, and may be deposited using standard electroforming techniques. In certain embodiments, the template metal may be chosen to protect the mandrel material from the environment or from chemicals used in the electroforming process. The template metal may also be used to protect the interface between the dielectric and exposed metal portion of mandrel. In further embodiments, the interface between the patterned dielectric and mandrel substrate can be protected from the environment by patterning a second dielectric at the interface. The template metal can also help prevent delamination of the dielectric by locking it in place. The template metal can also be deposited by vacuum coating techniques to allow for the deposition of metals such as titanium and stainless steel which will provide a low adhesion surface, facilitating the release of the metallic article and better protecting the interface between the dielectric and the mandrel substrate. In this case the template metal may require a second patterning step to confine it to the exposed metal region of the mandrel. Another common base metal application used in electroforming is electroless deposition, which is commonly used for placing metal for replication on complicated surface geometries. This method can also be used for creating the base metal for the mandrels discussed herein.

FIGS. 10A and 10B describe various layers that may be included on electroformed elements using the present methods. In FIG. 10A, an electroformed element 1000 has a bulk conductor material 1010, such as copper, with a barrier layer 1020 plated onto a top surface of the bulk conductor 1010, and a barrier layer 1030 plated on a bottom surface of the bulk conductor 1010. The bottom surface of electroformed element 1000 is configured to be facing the photovoltaic cell, such as providing a surface for attachment. The material for barrier layers 1020 and 1030 prevents corrosion of copper, and may be, for example, nickel, nickel boron, silver, tin, or tin-lead alloys. Electroformed element 1000 is fabricated by plating barrier layer 1030 in the mandrel, forming bulk conductor 1010 over barrier layer 1020, and then plating the top barrier layer 1020. Thus, barrier layers 1020 and 1030 surround bulk conductor 1010. In further embodiments, additional layers 1040 (indicated as a dashed line) may be deposited over barrier layer 1020. For example, layer 1040 may be a solder, which can later reflow and bond to screen-printed silver fingers on a photovoltaic cell for making electrical contact of the electroformed element 1000 to the cell. In other embodiments, layer 1040 may include a reflective material such as silver or tin, to enhance the optical properties of electroformed element 1000. For example, enhanced deflection and reflection provided by the top surface reduces the effective shading of the metallic article to less than its footprint.

FIG. 10B shows another embodiment of an electroformed element 1050, in which solder is applied to the bottom surface of an electroformed element rather than the top surface as in FIG. 10A. First, an initial layer 1060 is plated in the exposed metal region of mandrel 1052. Layer 1060 may be tin, lead, or any combination thereof. Next, a layer 1070 of copper is electrolessly deposited over layer 1060, such that the layers 1060 and 1070 are effectively part of the exposed metal region of the mandrel. The copper layer 1070 is deposited due to a reduction-oxidation reaction between copper sulfate and the metals of layer 1060 (tin, lead, or any combination of the two), and leaves a surface layer of loosely adhered copper on the top of the initial metal layer 1060. A solder layer 1080 is formed over copper layer 1070. The copper layer 1070 has poor adhesion to the solder, and therefore facilitates removal of electroformed element 1050 from mandrel 1052. The use of these metals in layers 1060-1080 for this purpose is contrary to known methods, because their reaction with copper has typically been seen as a negative feature during electroplating. The interaction of tin, lead, or any combination of the two, with copper produces a layer of very poorly adhered copper metal on the surface of the tin/lead. In conventional electroplating operations, this would eventually cause delamination of the electroplated part, and therefore is undesirable for conventional plating applications. In the present disclosure, the poorly adhered copper layer 1070 becomes an advantage, as it is able to create a release layer for whatever layer is being deposited over it, in this case, solder layer 1080.

Solder layer 1080 remains attached to the electroformed element 1050 when removed from the mandrel 1052. Barrier layer 1030 can, for example, then be plated onto the solder layer 1080, forming a bottom surface for bulk conductor 1010 as described for FIG. 10A. However, the plating of this layer 1030 is not required for attachment of the electroformed element 1050 to a photovoltaic cell. Bulk conductor 1010 is then formed, such as with an overplated configuration in this embodiment. Barrier layer 1020 may be plated over the top surface of bulk conductor 1010, and additional layer(s) 1040—such as a reflective material to achieve a desired surface finish—is deposited over barrier layer 1020. The electroformed element 1050 may then be separated from the mandrel 1052, as a free-standing metallic article.

Applying solder, such as layer 1040 in FIG. 10A or layer 1080 in FIG. 10B, to the electroformed element while the element is in the mandrel provides manufacturing benefits compared to performing a solder plating step after the electroformed article is removed or peeled from the mandrel. By applying the solder during electroforming of the metallic article, before removing the electroformed article from the mandrel, a separate plating tool for applying solder is eliminated from the process, thus reducing cost. In the embodiment of FIG. 10B, applying solder 1080 only on the bottom side of electroformed element 1050 provides a further benefit by allowing the top surface to be coated with a different material than the bottom surface. Thus, in FIG. 10B the light-facing surface of electroformed element 1050 (e.g., top surface 1020) may be optimized differently from the attach surface (e.g., bottom surface 1030). In embodiments where solder is applied only to the top surface (e.g., layer 1040) before the electroformed element 1050 is removed from the mandrel 1052, the solder may be later reflowed to coat the entire surface of electroformed element 1050 during attachment to a photovoltaic cell.

FIGS. 11A-11C illustrate another embodiment in which edge surfaces of the overplated portion may be further enhanced. In FIG. 11A, an electroformed element 1100 is formed in electrically conductive mandrel 1150 as in any of the previous embodiments. In FIG. 11B, an edge region 1120 at the interface between electroformed element 1100 and an outer surface 1153 of mandrel 1150 is etched, such as using a ferric chloride or ammonium persulfate solution in the case of a copper electroform. In various embodiments, any wet chemical etchant may be used that will selectively etch the electroformed metal without damaging the mandrel surface. As a result, the edge region 1120 is etched back to expose additional surface area where desired coating layers may not have been able to be applied. After etching, the edge region 1120 may be coated or plated as shown in FIG. 11C. For example, edge region 1120 may be plated with the same barrier metal as the rest of the electroformed element (e.g., top barrier layer 1020 and bottom barrier layer 1030 of FIG. 10A) to more completely encapsulate electroformed element 1100. In other embodiments, edge portion 1120 may be textured or coated for modifying reflective properties. Plating edge region 1120 while still on the mandrel 1150 simplifies manufacturing and therefore reduces cost compared to performing separate plating steps after the metallic article is removed from the mandrel.

FIG. 12 is a flowchart 1200 of an exemplary method of manufacturing an electrical component for a photovoltaic cell. First, in step 1210 an electrically conductive mandrel with an outer surface layer having dielectric regions and exposed metal regions is provided, such as those described in relation to FIGS. 1-4. The exposed metal regions include a preformed pattern that may include a groove. In some embodiments, the groove may be at least partially plated with a metal in step 1220. The metal may be a template metal to impart a shape to the electroformed element, such as in FIG. 9. In other embodiments, the exposed metal region may be plated with one or more metal layers to facilitate release of the electroformed piece from the mandrel, to provide a barrier layer to the bulk conductor, and/or to plate solder onto the electroformed article as in FIGS. 10A-10B. In step 1230, the metallic article is electroformed, where at least one electroformed element in the metallic article has an overplated portion. The metallic article is fabricated from a bulk conductor material to serve as an electrical conduit for a photovoltaic cell. In step 1240, additional layers such as surface finishes, barrier layers, and/or solder are applied on the bulk conductor. Etching of the edge region of the overplated portion may be performed in step 1250, as described in relation to FIGS. 11A-11C, and additional layers may be applied to the edge region after etching. In step 1260, the metallic article is separated from the electroforming mandrel.

It can be seen that the free-standing electroformed metallic article described herein is applicable to various cell types and may be inserted at different points within the manufacturing sequence of a solar cell. Furthermore, the electroformed electrical conduits may be utilized on either the front surface or rear surface of a solar cell, or both. In addition, although the embodiments herein have primarily been described with respect to photovoltaic applications, the methods and devices may also be applied to other electronic and semiconductor applications such as redistribution layers (RDL's), flex circuits, light emitting diodes, integrated circuits, and discrete components for electronic circuit boards. Furthermore, the flow chart steps may be performed in alternate sequences, and may include additional steps not shown. Although the descriptions have described for full size cells, they may also be applicable to half-size or quarter-size cells. For example, the metallic article design may have a layout to accommodate the cell having only one or two chamfered corners instead of all four corners being chamfered as in a mono-crystalline full pseudosquare.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only, and is not intended to limit the invention.

What is claimed is:

1. A method of forming a metallic article for a photovoltaic cell, the method comprising:
providing an electrically conductive mandrel having an outer surface layer comprising a preformed pattern, the outer surface layer having a dielectric region and an exposed metal region;
electroforming a metallic article, the metallic article comprising a plurality of electroformed elements formed on the exposed metal region of the outer surface layer of the electrically conductive mandrel, wherein a first electroformed element in the plurality of the electroformed elements has an overplated portion formed above the outer surface layer; and
separating the metallic article from the electrically conductive mandrel, wherein the plurality of electroformed elements are interconnected such that the metallic article forms a unitary, free-standing piece when separated from the electrically conductive mandrel, and
wherein the plurality of electroformed elements are configured to serve as an electrical conduit for the photovoltaic cell.

2. The method of claim 1 wherein a height of the overplated portion comprises at least a majority of a height of the first electroformed element.

3. The method of claim 1 wherein the exposed metal region is a surface of the electrically conductive mandrel.

4. The method of claim 1 wherein the exposed metal region comprises:
a first layer comprising at least one of tin and lead; and
a second layer comprising copper, the second layer being over the first layer.

5. The method of claim 1 wherein the preformed pattern comprises a groove in the outer surface layer, wherein the first electroformed element is formed in the groove.

6. The method of claim 5 further comprising filling the groove with a template metal prior to the electroforming.

7. The method of claim 6 wherein the template metal comprises an outer surface having a convex contour on which the first electroformed element is formed.

8. The method of claim 1 wherein the electroforming comprises:
forming a bulk conductor layer;
forming a first barrier material layer on a bottom surface of the bulk conductor layer, wherein the bottom surface is configured to be facing the photovoltaic cell; and
forming a second barrier material layer on a top surface of the bulk conductor layer.

9. The method of claim 8 wherein the electroforming further comprises forming a layer of solder over the first barrier material layer; and
forming a layer of a reflective material over the second barrier material layer.

10. The method of claim 8 wherein the electroforming further comprises forming a layer of solder over the second barrier material layer.

11. The method of claim 1 further comprising etching an edge portion of the overplated portion prior to separating the metallic article from the electrically conductive mandrel, wherein the edge portion is located at an interface between the overplated portion and the mandrel, and wherein etching removes material from the edge portion.

12. The method of claim 11 further comprising plating the edge portion after the etching.

13. The method of claim 1 wherein the first electroformed element and a second electroformed element in the plurality of electroformed elements are coplanar with each other such that the first coplanar electroformed element has a first cross-section that overlaps a majority of a second cross-section of the second coplanar electroformed element.

14. An electrical component for a photovoltaic cell, the electrical component comprising:
a metallic article comprising a plurality of electroformed elements, wherein a first electroformed element in the plurality of the electroformed elements has an overplated portion;
wherein the plurality of electroformed elements are interconnected such that the metallic article forms a unitary, free-standing piece, and
wherein the plurality of electroformed elements are configured to serve as an electrical conduit for a photovoltaic cell.

15. The electrical component of claim 14 wherein a height of the overplated portion comprises a majority of a height of the first electroformed element.

16. The electrical component of claim 14 wherein the overplated portion comprises:
a bulk conductor layer; and
a first barrier material layer on a bottom surface of the bulk conductor layer, wherein the bottom surface is configured to be facing the photovoltaic cell; and
a second barrier material layer on a top surface of the bulk conductor layer.

17. The electrical component of claim 16 wherein the overplated portion further comprises a layer of solder over the first barrier material layer; and
a layer of a reflective material over the second barrier material layer.

18. The electrical component of claim 16 wherein the overplated portion further comprises a layer of solder over the second barrier material layer.

19. The electrical component of claim 16 wherein the barrier material comprises nickel.

20. The electrical component of claim 14 wherein the plurality of electroformed elements comprises a continuous grid pattern.

21. The electrical component of claim 14, wherein the first electroformed element and a second electroformed element in the plurality of electroformed elements are coplanar with each other such that the first coplanar electroformed element has a first cross-section that overlaps a majority of a second cross-section of the second coplanar electroformed element.
